(19) United States
(12) Patent Application Publication
(10) Pub. No.: US 2006/0049435 A1
(43) Pub. Date: Mar. 9, 2006

(54) Vertical JFET as used for selective component in a memory array

(75) Inventors: Colin S. Bill, Cupertino, CA (US); Michael A. Van Buskirk, Saratoga, CA (US)

Correspondence Address: AMIN & TUROCY, LLP, 1900 EAST 9TH STREET, NATIONAL CITY CENTER, 24TH FLOOR,, CLEVELAND, OH, 44114, US

(73) Assignee: SPANSION, LLC, Sunnyvale, CA (US)

(21) Appl. No.: 10/935,301

(22) Filed: Sep. 7, 2004

(51) Int. Cl. H01L 29/80

(52) U.S. Cl. 257/278

(57) ABSTRACT

Systems and methods are disclosed that facilitate providing a selective functionality to a polymer memory cell in a memory array while increasing device density in the memory cell array. A vertical JFET is described to which voltages can be selectively applied to control internal current flow there through, which in turn can be employed to manipulate the state of a polymer memory cell coupled to the vertical JFET. By mitigating gaps between gates, or wordlines, and drains of the vertical JFETs, feature size can be reduced to permit increased device density. Furthermore, vertical JFETs in the array can be coupled to gates on only two opposite sides, permitting the JFETs to be arranged without gate crossbars between them, further increasing device density. In this manner, the present invention provides switching characteristics to a memory cell and overcomes problematic bulkiness associated with conventional MOS devices.

### TECHNICAL FIELD

The present invention relates generally to semiconductor fabrication, and more particularly to systems and methodologies that facilitate increased memory density via utilizing vertically oriented JFETs in a memory array.

### BACKGROUND OF THE INVENTION

In the semiconductor industry, there is a continuing trend toward higher device densities. To achieve these high device densities there have been, and continue to be, efforts toward scaling down device dimensions (e.g., at sub-micron levels) on semiconductor wafers. In order to accomplish such densities, smaller feature sizes and more precise feature shapes are required. This may include width and spacing of interconnecting lines, spacing and diameter of contact holes, and surface geometry, such as corners and edges, of various features. The dimensions of and between such small features can be referred to as critical dimensions (CDs). Reducing CDs and reproducing more accurate CDs facilitates achieving higher device densities.

Semiconductors have permeated into every aspect of modern society. They are the building blocks used to create everything from the information super-highway to the electronic timer in the family toaster. Generally, any device that is used today that is considered “electronic” utilizes semiconductors. These often-unseen entities help to reduce the daily workload, increase the safety of our air traffic control systems, and even let us know when it is time to add softener to the washing machine. Modern society has come to rely on these devices in almost every product produced today. And, as we progress further into a technologically dependent society, the demand for increased device speeds, capacity and functionality drive semiconductor manufacturers to push the edge of technology even further.

A substantial amount of the semiconductors produced today are slated for the computer industry either as internal components or display components. Often, what we associate as “computer related” devices are used separately in products found in every day use. Flat panel screens are found in TV sets, handheld games, and even refrigerators. Computer chips are found in toasters, cars and cell phones. All of these common devices are possible due to the semiconductor. As the demand for more enhanced products increases, manufacturers must produce higher quality and, at the same time, cheaper semiconductor devices.

A growing area of manufacturing concentration has been on those components which can provide a building block for higher-level applications. These may include such components as memory, light emitting diodes (LEDs) and other semiconductor cells. Memory cells, for example, are used to store information. This simple device is found in some of the world's fastest computers and the most sophisticated electronics. Being able to store information allows society to reuse data repeatedly. At the start of the electronic revolution, only a few bits of information could be stored. Today, we coin new words, such as gigabyte and terabyte, to describe the magnitude of the amount of information that can be stored, beyond most people's imaginations. This push towards larger and faster information storage and retrieval requires that semiconductors must be continuously improved to keep up with demand. LEDs have likewise pervaded our society as memory semiconductors have. They are used in displays, signs and signaling devices. They also continue to be revised, improved and advanced to keep in pace with our growing appetite for technology.

Generally, the control of a semiconductor device is accomplished through the utilization of electricity. A voltage is placed across the device to put it in a predetermined state, thus “controlling” it. Depending on the device being subjected to the voltage, it may store a value represented by the state or it may turn the device ON or OFF. If the device is a memory cell, it may be programmed to read, write or erase based on the voltage level and polarity. If the device is an LED, application of the voltage may turn the emitter ON or OFF, reduce its brightness or increase its brightness. Thus, it is imperative for proper operation of these types of devices that there is a means to control the application and level of the voltages across them. Current manufacturing techniques utilize, for example, metal oxide semiconductor field emitter transistors (MOSFETs) to achieve such goals. MOSFETS, however, can be bulky and thus are not particularly suited to devices wherein high density is a paramount priority in today's semiconductor industry, which strives daily to reduce size and increase capacity of semiconductor devices.

### SUMMARY OF THE INVENTION

The following presents a simplified summary of the invention in order to provide a basic understanding of some aspects of the invention. This summary is not an extensive overview of the invention. It is not intended to identify key/critical elements of the invention or to delineate the scope of the invention. Its sole purpose is to present some concepts of the invention in a simplified form as a prelude to the more detailed description that is presented later.

The present invention provides for systems and methods that facilitate increasing memory device density and improving the quality of switching device(s) employed in polymer memory arrays. According to an aspect of the invention, a vertical JFET can be employed as a switching device in a polymer memory cell array in order to mitigate bulkiness associated with employing typical metal-oxide semiconductor (MOS) devices. This aspect of the invention permits a greater device density in polymer memory cell arrays than previously attainable via employing bulky MOS-type, diode, and/or horizontal JFET devices and mitigates the need for a high-density diode solution to providing a selective component to a memory cell.

According to another aspect of the invention, critical dimensions of a vertical JFET can be reduced via mitigating all or part of a spacing between a vertical JFET gate and drain. For example, a vertical JFET can be constructed that has no gap between the gate and drain thereof, which facilitates providing a selective component to an associated polymer memory cell while further increasing device density in a polymer memory cell array.

According to yet another aspect of the invention, a common gate, or wordline, can be constructed to contact a plurality of vertical JFETs, such that wordline crossbars between vertical JFETs can be absent to facilitate arranging vertical JFETs in closer proximity to each other than is possible in the presence of wordline crossbars. In this manner, even greater device density can be achieved in polymer memory arrays. For example, device size for the polymer memory cell with vertical JFET of the present invention can be reduced from about 15 features-squared down to about 8 features-squared.

To the accomplishment of the foregoing and related ends, certain illustrative aspects of the invention are described herein in connection with the following description and the annexed drawings. These aspects are indicative, however, of but a few of the various ways in which the principles of the invention can be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

FIG. 1 is a schematic illustration of a simple junction field-effect transistor (JFET) in accordance with an aspect of the present invention.

FIG. 2 is an illustration of a more detailed JFET device, in order to facilitate exemplary discussion of JFET operation, in accordance with an aspect of the present invention.

FIG. 3 is an illustration of a typical JFET device and accompanying circuit proffered to facilitate explanation of JFET functionality in accordance with various aspects of the present invention.

FIG. 4 is an illustration of a top view of a vertical JFET in accordance with an aspect of the present invention.

FIG. 5 is an illustration of a cross-sectional view of a vertical JFET in accordance with an aspect of the present invention.

FIG. 6 is an illustration of a top-view of a polymer memory cell array with vertical JFETs in accordance with an aspect of the present invention.

FIG. 7 is an illustration of a cross-section of a polymer memory cell with vertical JFET in accordance with an aspect of the present invention.

FIG. 8 is an illustration of a vertical JFET that exhibits smaller critical dimensions than previously attainable, in accordance with an aspect of the present invention.

FIG. 9 is an illustration of an array of polymer memory cells with vertical JFETs that facilitates further reduction of critical dimension of the memory cells in accordance with an aspect of the present invention.

FIG. 10 is an illustration of a methodology employing vertical JFET in a polymer memory cell array in accordance with an aspect of the present invention.

FIG. 11 is an illustration of a methodology that facilitates reducing the critical dimension of a vertical JFET and associated memory cell in accordance with an aspect of the present invention.

FIG. 12 is an illustration of a methodology that further facilitates critical dimension reduction in the vertical JFET and memory cell in accordance with an aspect of the present invention.

### DETAILED DESCRIPTION OF THE INVENTION

The present invention will now be described with reference to the drawings, wherein like reference numerals are used to refer to like elements throughout. The present invention will be described with reference to systems and methods increasing memory density and switching device quality in a polymer memory array. It should be understood that the description of these exemplary aspects are merely illustrative and that they should not be taken in a limiting sense.

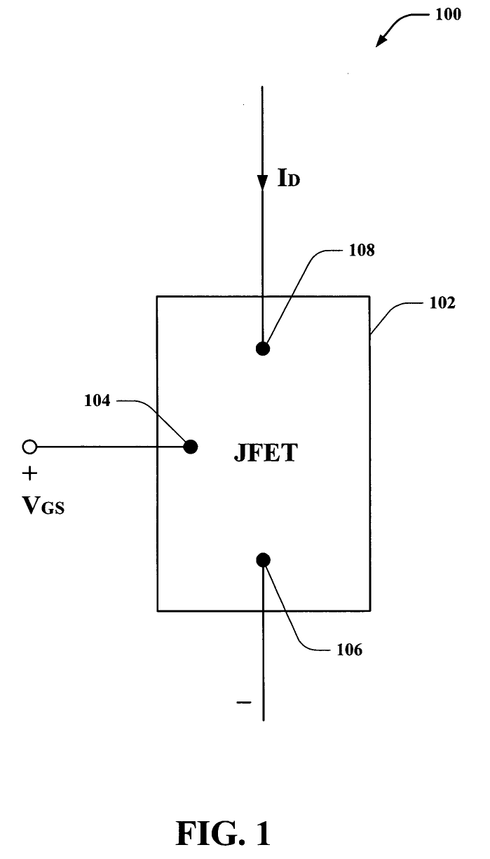

FIG. 1 is an illustration of a simple junction field-effect transistor (JFET) schematic 100 presented for exemplary purposes and to provide insight into JFET operation. A JFET is a three-terminal device that has numerous applications, many of which comprise providing a functionality similar to, and/or in place of, for example, a bipolar junction transistor (BJT). A FET differs from a BJT in that a BJT is a bipolar, current-controlled device whereas a FET is a unipolar, voltage-controlled device (e.g., amplifier, etc.). As illustrated, the JFET 102 comprises a gate 104, a source 106, and a drain 108. A voltage V_{GS} (voltage from gate-to-source) can be applied across the gate in order to effectuate control over the amount of current permitted to flow through the JFET. Thus, the current I_{D} (current through the drain) is a function of the control voltage V_{GS} applied to the input circuit. Typical FET operation is effectuated by establishing an electrical field via extant charges, which can facilitate control of a conduction path in the output circuit while mitigating the need for direct contact between the controlling entity and the controlled entity. Advantages of employing the JFET of the present invention comprise smaller size and better temperature stability than is exhibited by conventional BJTs. Moreover, a JFET can be constructed with smaller critical dimensions than, for example, a metal-oxide semiconductor field-effect transistor (MOSFET), making the JFET the FET of choice when device density and temperature stability are considered. For example, the JFET of the present invention is optimally suited for a polymer memory array, wherein device density is of paramount importance and temperature stability is increasingly evaluated due to the rising power consumption (and related heat dissipation) of modem computing devices. Additionally, the JFET of the present invention can provide a selective element to a polymer memory cell in order to facilitate application of a plurality of such cells in a polymer memory cell array.

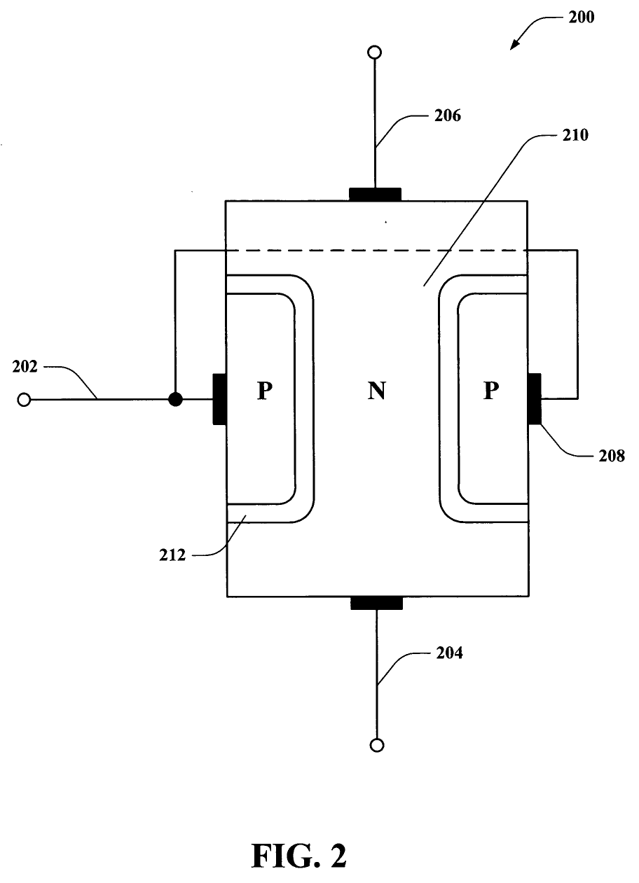

FIG. 2 illustrates a more detailed JFET device 200, in order to facilitate exemplary discussion of JFET operation. The JFET 200 comprises a gate 202 that is operably coupled to regions of the JFET that comprise a p-type material, while a source 204 and drain 206 are operably coupled to a region comprising n-type material. In this example, an n-channel JFET is depicted, which is named for the large central region of the JFET 200 comprising n-type material. The actual n-channel is numerically identified as 210 in FIG. 2. However, it is to be understood that the present invention can employ a p-channel JFET and is not limited to the n-channel JFET depicted in FIG. 2.

Each of the gate 202, source 204, and drain 206 is connected to the JFET proper by an ohmic contact 208, which can provide a relatively low resistance that is independent of any applied voltage. Depletion regions 212 are illustrated at the boundaries of the p-n junctions where the n-channel 210 abuts the p-type material. The depletion regions 212 are substantially devoid of free carriers (e.g., “holes,” etc.) that can carry electrons, and therefore no conduction can occur through the depletion regions 212. Thus, conduction of electrical current from source to drain can only occur through the n-channel 210 of the JFET 200.

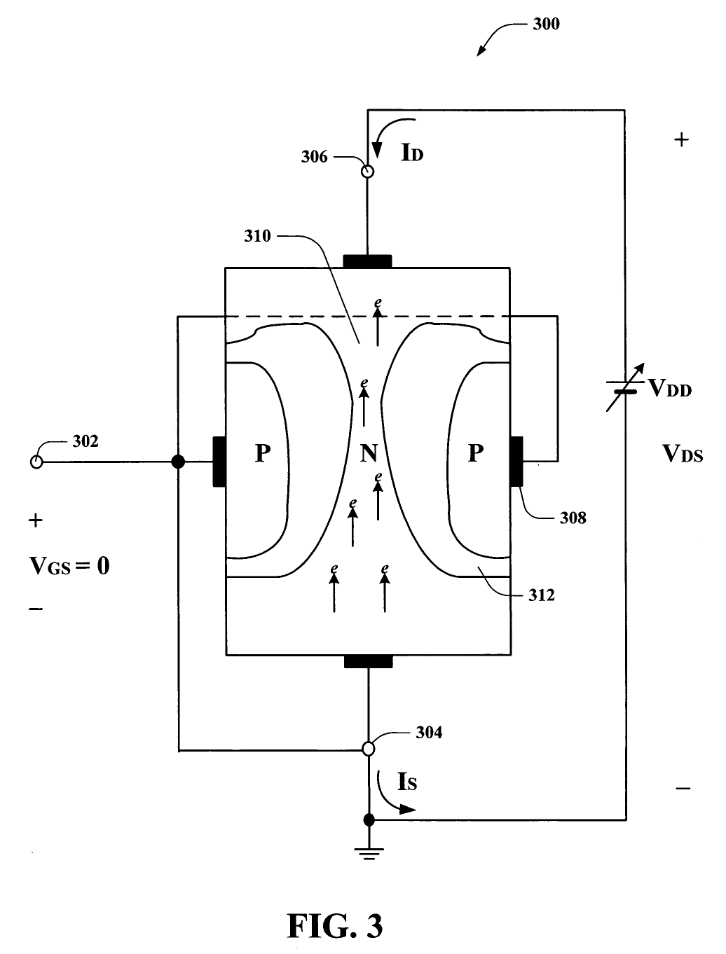

FIG. 3 is yet another illustration of a typical JFET device 300 and accompanying circuit proffered to facilitate explanation of JFET functionality in accordance with various aspects of the present invention. The JFET 300 comprises a gate 302, and source 304, and a drain 306, all of which are coupled to the JFET proper via ohmic regions 308. FIG. 3 further depicts an n-channel 310 through which electrons (and therefore current) can flow. It will be noted that electron flow and current flow are depicted in opposing directions as conventional positive current flows opposite to the direction of electron displacement. As illustrated, the depletion regions 312 are swollen at their respective upper portions, resulting an a narrower, or “pinched,” n-channel 310 as compared to the n-channel 210 of FIG. 2. This in turn results in a reduction in the number of electrons permitted to pass through the n-channel 301 in a given time period. The following equation defines current flow:
I=−1(q/t),
where I is current in Amperes, q is charge measured in Coulombs (approximately equivalent to 6.24×10¹⁸ electrons), t is time in seconds, and the −1 is a convention employed to indicate that current flows in a direction opposite to that of electron flow. It follows then that reducing the number of electrons permitted to flow through the pinched n-channel 310 will also reduce the magnitude of the current permitted to flow there through in the opposite direction, because electron flow and current flow are inextricably linked together.

According to the figure, a positive voltage V_{DS} has been applied to the circuit. Furthermore, the gate 302 has been connected to the source 304 in order to ensure that the voltage from gate to source, V_{GS}, is zero. When voltage V_{DD} is applied to the drain 306, electrons will be drawn to the drain end of the n-channel 310, which will establish current I_{D} in the opposite direction (e.g., toward the source 304). Depending on the magnitude of V_{DD} (which equals V_{DS} in this example), the current can be controlled at a value between 0 and I_{DSS}, which is a maximum current from drain to source at a saturation point.

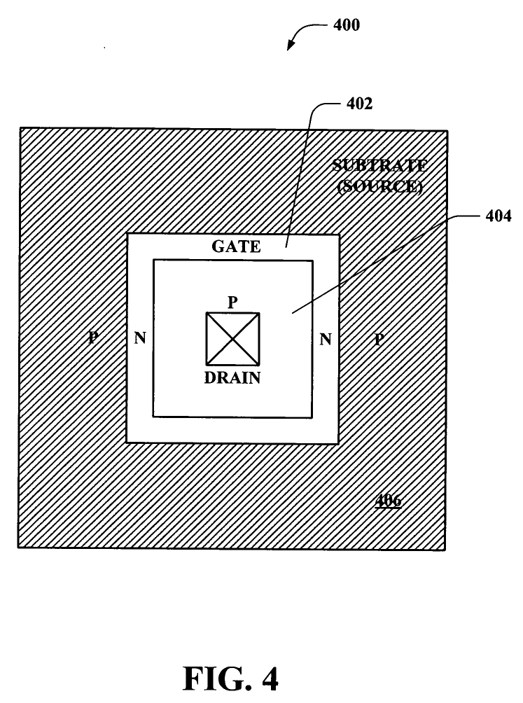

FIG. 4 is an illustration of a top view of a vertical JFET 400 in accordance with an aspect of the present invention. As illustrated, the vertical JFET 400 comprises a gate 402 that, according to this example, comprises an n-type extrinsic semiconductor material. The n-type extrinsic semiconductor material has typical donor properties. For example, the n-type gate can be formed of a material comprising silicon (or, e.g., germanium, etc.), that can be doped by a pentavalent impurity element (e.g., arsenic, antimony, phosphorus, etc.). The pentavalent impurity element can form 4 covalent bonds with silicon atoms, which leaves a fifth electron unbound by the impurity element.

The gate 402 surrounds a drain 404 comprising a p-type channel material. A p-type substrate acts as a source 406 for the vertical JFET 400. A p-type source is a source of holes (e.g., free carriers, etc.) rather than electrons: however, the present invention is not limited to the p-channel JFET described in this and following examples, but rather additionally and/or alternatively can comprise an n-channel JFET. The p-type material of the drain 404 and the substrate 406 can comprise silicon (or, e.g., germanium, etc.), that can be doped by a trivalent impurity element (e.g., boron, gallium, indium, etc.). The impurity elements can form only three covalent bonds with silicon atoms in the substrate 406, such that each impurity atom has a hole that can accept an electron. When a valence electron on a silicon atom acquires sufficient kinetic energy to break its covalent bond with the silicon atom, it can fill the hole, or vacancy, at the impurity atom, which in turn creates a new hole at the donating silicon atom. Holes can thus propagate from the p-type substrate 406 toward the p-type drain 404.

Depletion regions (not shown) can be formed that can be manipulated to control current flow through the vertical JFET 400. Such manipulation can be performed via adjusting voltages from drain to source. This aspect of the JFET is particularly suited for employment in, for example, memory cell arrays that require a selective element to read, write, and or erase information in a memory cell while maintaining high device density.

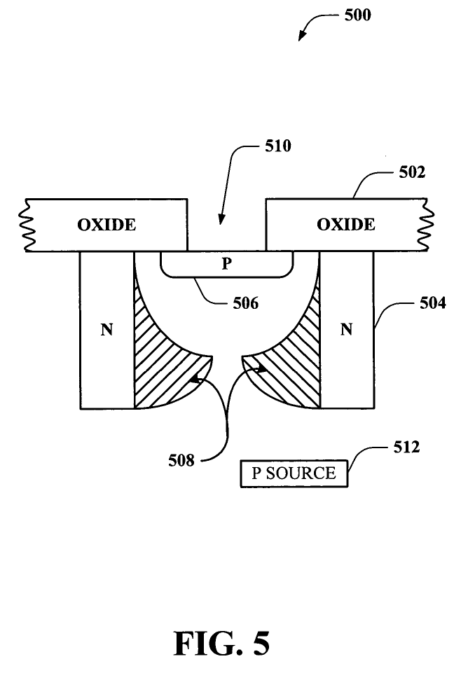

FIG. 5 illustrates a cross-sectional view of a vertical JFET 500 described in FIG. 4. According to the illustration, an oxide 502 overlies an n-type gate 504 that surrounds a p-type drain 506. Application of sufficient voltage across the JFET will cause depletion regions 508 to be formed, which can be manipulated via voltage adjustment to control current flow. A contact hole 510 in the oxide 502 permits the p-type drain to be implanted through the contact hole 510. A free-carrier source 512 is shown that can provide holes when a voltage is applied to the vertical JFET 500 in order to facilitate creation and/or adjustment of the depletion regions 508, which in turn permits control of the current passed by the vertical JFET 500. The vertical JFET 500 is thus a voltage-controlled device wherein a small change in applied voltage can facilitate a substantially greater change in output current. The reduced size of the vertical JFET 500 as compared with conventional JFETs, MOSFETS, BJTs, etc., makes the vertical JFET an optimal selective element for utilization in conjunction with polymer memory cells and/or arrays thereof.

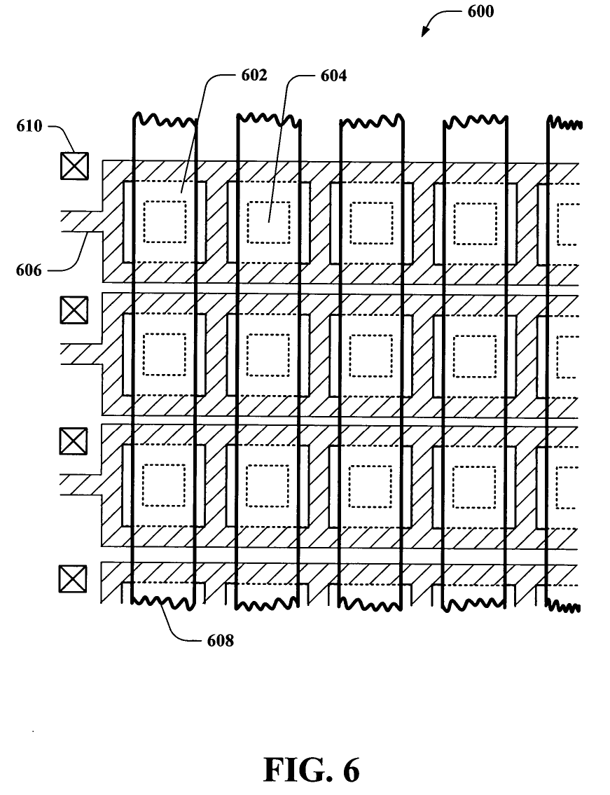

FIG. 6 is a top-view of a polymer memory cell array 600 with a vertical JFET in accordance with an aspect of the present invention. The polymer memory cell array 600 comprises a polymer memory cell 602 that is operably coupled to a vertical JFET 604. The vertical JFET 604 can be employed to facilitate selection of a state for the polymer memory cell (e.g., on, off, read, write, erase, etc.) The vertical JFET comprises a gate 606 (e.g., a wordline, etc.) that facilitates manipulation of the output current of the vertical JFET 604 via adjustment of an applied voltage or electric field. It is to be appreciated that the wordline, or gate, 606 can be common to a plurality of vertical JFETs 604, as illustrated in FIG. 6, because a single voltage V_{GS} can be applied to all vertical JFETs 604 in the wordline 606 to provide a constant voltage from gate to source. The polymer memory cell array 600 further comprises a bitline(s) 608 that contacts the top of a polymer memory cell(s) 602 in order to permit an instant voltage (e.g., V_{DS}, etc.) to be applied to the vertical JFET. The applied voltage can create swollen depletion regions (not shown) of varying magnitudes to constrict the conduction channel through the vertical JFET 604 in order to control current flow there through, which in turn can facilitate control of memory cell state(s).

It is to be understood that the bitline 608 can be comprised of a conductive material such as, aluminum, chromium, copper, germanium, gold, magnesium, manganese, indium, iron, nickel, palladium, platinum, silver, titanium, zinc, alloys thereof, indium-tin oxide, polysilicon, doped amorphous silicon, metal silicides, and the like. Exemplary alloys that can be utilized for the conductive material include Hastelloy®, Kovar®, Invar®, Monel®, Inconel®, brass, stainless steel, magnesium-silver alloy, and various other alloys. The thicknesses of the wordline 606 and/or the bitline 608 can vary depending on the implementation and the memory device being constructed.

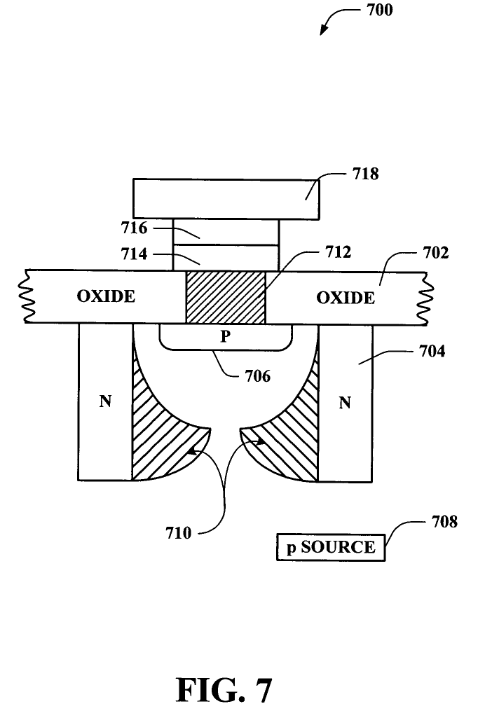

Turning now to FIG. 7, a cross-section of a polymer memory cell with vertical JFET 700 is illustrated in accordance with an aspect of the present invention. The memory cell with JFET 700 comprises an oxide layer 702 (e.g., silicon dioxide (SiO₂), etc.) that overlies a gate 704 and a drain 708. A free-carrier source 708 is illustrated that provides holes that can propagate through depletion regions 710 associated with the gate, or wordline, 704. The oxide layer 702 comprises a contact hole through which the drain 706 can be implanted prior to insertion of a metal contact 712 into the contact hole.

A passive layer 714 can be formed over the metal contact 712 using conventional methods to facilitate conductivity in the polymer memory cell with vertical JFET 700. The passive layer 714 can contain at least one charge carrier assisting material that contributes to the controllable conductive properties of the polymer memory cell with vertical JFET 700. The charge carrier assisting material has the ability to donate and accept charges (holes and/or electrons). Generally, the charge carrier assisting material has at least two relatively stable oxidation-reduction states. The two relatively stable states permit the charge carrier assisting material to donate and accept charges and electrically interact with the polymer memory cell with vertical JFET 700. The particular charge carrier assisting material employed is selected so that the at least two relatively stable states match with the at least two relatively stable states of the polymer memory cell with vertical JFET 700.

Examples of charge carrier assisting material that may make up the passive layer 714 can comprise one or more of the following: nickel arsenide (NiAs), cobalt arsenide (CoAs₂), copper sulfide (Cu₂S, CuS), copper oxide (CuO, Cu₂O), manganese oxide (MnO₂), titanium dioxide (TiO₂), indium oxide (I₃O₄), silver sulfide (Ag₂S, AgS), iron oxide (Fe₃O₄), and the like. The passive layer 714 is typically grown using oxidation techniques, formed by gas phase reactions, etc. The passive layer 714 has a suitable thickness that can vary according to the implementation and/or memory device being fabricated.

A polymer layer 716 overlies the passive layer 714 and forms the memory component of the polymer memory cell with vertical JFET 700. The polymer layer 716 can be, for example, a conjugated organic polymer. Such conjugated molecules are characterized in that they have overlapping π orbitals and that they can assume two or more resonant structures. The organic molecules can be cyclic or acyclic, and can be capable of self-assembly during formation or deposition. Examples of conjugated organic materials comprise one or more of polyacetylene (cis or trans); polyphenylacetylene (cis or trans); polydiphenylacetylene; polyaniline; poly (p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Additionally, the properties of the polymer can be modified by doping with a suitable dopant. It is to be appreciated that the polymer layer 716 can comprise inorganic material(s), and is not limited to organic polymers.

It is to be appreciated that the passive layer 714 and/or the polymer layer 716 can be formed by a number of suitable techniques, some of which are described above. One suitable technique that can be utilized is a spin-on technique that involves depositing a mixture of the polymer/polymer precursor and a solvent, and then removing the solvent from the substrate/electrode. Another technique is chemical vapor deposition (CVD) optionally including a gas reaction, gas phase deposition, and the like. CVD can comprise low-pressure chemical vapor deposition (LPCVD), plasma enhanced chemical vapor deposition (PECVD), and high density chemical vapor deposition (HDCVD), etc.

A metal bitline 718 is illustrated over the polymer layer 716, which can provide interconnectivity functionality for the polymer memory cell with vertical JFET 700 in order to permit manipulation of applied voltage(s) across the vertical JFET, which further permits control of current flow through the vertical JFET. For example, an appropriate bitline 718 and wordline 704 that intersect the polymer memory with vertical JFET device 700 can be energized to an appropriate voltage level necessary for the desired function (e.g. read, write, erase). All devices along the appropriate bitline 718 and wordline 704 are affected by the change in voltage levels. However, only the device 700 at the intersection of the appropriate bitline 718 and wordline 704 actually changes to the appropriate state. It is the combination of the two voltage level changes that alters the device 700 state. The bitline voltage level alone and the wordline voltage level alone are not enough to program the other devices connected to these lines. Only the memory with JFET device 700 that is connected to both lines will realize the desired threshold voltage levels for programming (e.g., read, write, erase, etc.) of the present invention. Additionally, it is also pertinent that the remaining bitlines and wordlines are set such that the remaining memory cells in an array are undisturbed during the processes. In this manner, the polymer memory cell with vertical JFET 700 can be programmed.

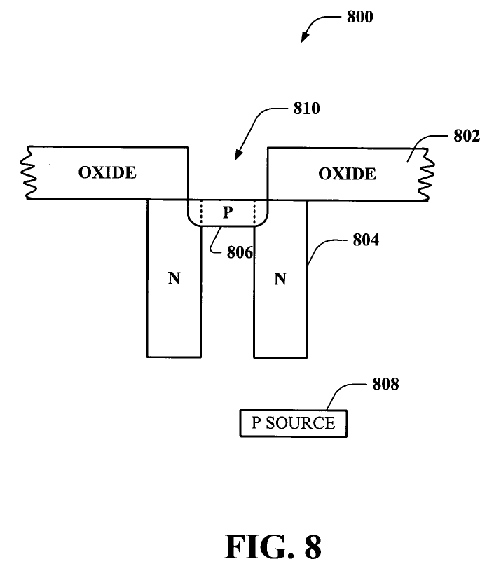

FIG. 8 is an illustration of a vertical JFET 800 that exhibits smaller critical dimensions than previously attainable, in accordance with an aspect of the present invention. The vertical JFET 800 comprises an oxide layer 802 position atop a gate 804 and a drain 806. A source 808 is illustrated, which provides free-carriers to the p-channel JFET depicted, although it is to be understood that the vertical JFET described with reference to FIG. 8 (as well as all other figures described herein) can be an n-channel JFET, in which case the gate 804 can comprise ap-type material, and the drain 806 and source 808 can comprise an n-type material, wherein the source can provide and the drain can receive electrons. The source 808 can be a substrate comprising p-type material (or n-type material if the vertical JFET is an n-channel JFET, etc.) upon which the illustrated vertical JFET 800 is positioned. The oxide layer 802 comprises a contact hole 810 through which the drain 806 can be implanted.

According to this aspect of the invention, the spacing between the gate 804 and the contact hole 810 can be reduced and/or eliminated to achieve smaller critical dimension with regard to the total space occupied by the vertical JFET 800. (See, e.g., FIG. 7, illustrating a slight gap between the gate 704 and the contact 712.) As illustrated in FIG. 8, the gate 804 overlaps slightly with the contact hole, and implantation of the drain (p-type material, in this example) through the contact hole facilitates achievement of the smaller critical dimension(s). In this manner, polymer memory cell size can be reduced from 3 features-by-5 features, or 15f², to 2 features-by-4 features, or 8f², which is 3f² smaller than, for example, a typical flash memory cell (e.g., flash memory cell is about 11f²).

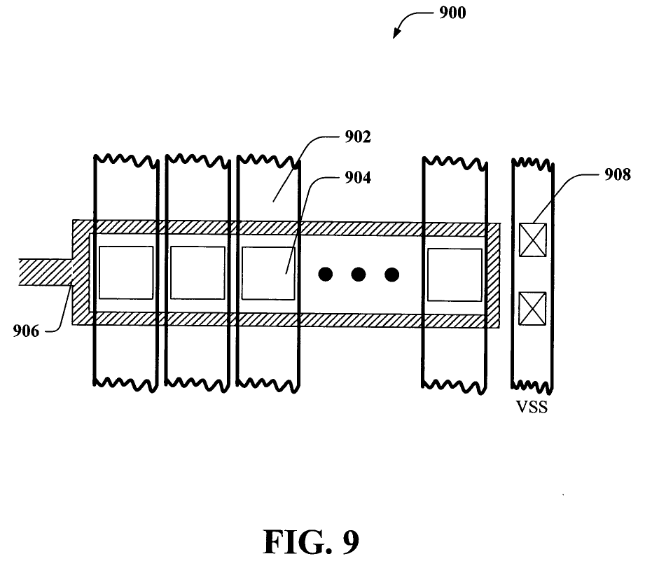

FIG. 9 illustrates an array of polymer memory cells with vertical JFETs 900 that facilitates further reduction of critical dimension of the memory cells in accordance with an aspect of the present invention. The memory cell(s) comprises bitlines 902 that overlie vertical JFETs 904 as described with reference to various other figures presented herein. The vertical JFETs are operably coupled to a gate, or wordline, 906, in a manner similar to that described in reference to FIG. 6. According to the present example, crossbars in the gate (e.g., portions of the gate extending between the vertical JFETs) are absent, which permits the vertical JFETs to be positioned in closer proximity to each other, thereby mitigating the amount of space occupied by each individual JFET and facilitating greater device density. Each JFET remains connected to the gate 906 despite the absence of gate crossbars, so that a gate voltage can be applied to each JFET to enable JFET function. Substrate contacts 908 are provided to complete the structure and functional connectivity of the vertical JFET in the array of polymer memory cells with vertical JFETs 900. In this manner, further reduction of critical dimension of the described device can be achieved.

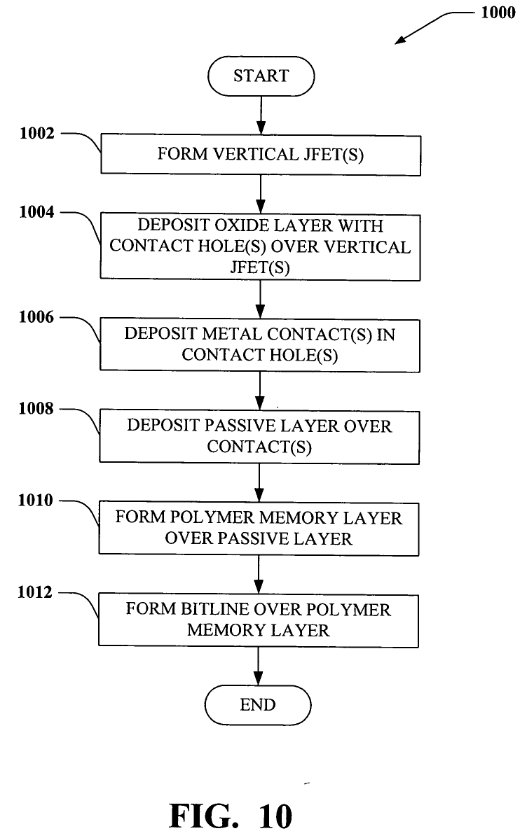

Turning briefly to FIGS. 10, 11, and 12, methodologies that can be implemented in accordance with the present invention are illustrated. While, for purposes of simplicity of explanation, the methodologies are shown and described as a series of blocks, it is to be understood and appreciated that the present invention is not limited by the order of the blocks, as some blocks can, in accordance with the present invention, occur in different orders and/or concurrently with other blocks from that shown and described herein. Moreover, not all illustrated blocks may be required to implement the methodologies in accordance with the present invention.

FIG. 10 is an illustration of a methodology 1000 employing vertical JFET in a polymer memory cell array in accordance with an aspect of the present invention. At 1002, a vertical JFET can be formed on a substrate. An oxide layer (e.g., silicon dioxide, etc.) can be deposited using conventional methods at 1004, and can have contact holes formed therein that align with the vertical JFETs. At 1006, metal contacts can be deposited in the contact holes to facilitate providing conductivity for the vertical JFET and memory cells. At 1008, a passive layer can be deposited over the metal contacts, which can comprise at least one charge carrier assisting material, such as, for example, nickel arsenide (NiAs), cobalt arsenide (CoAs₂), copper sulfide (Cu₂S, CuS), copper oxide (CuO, Cu₂0), manganese oxide (MnO₂), titanium dioxide (TiO₂), indium oxide (I₃O₄), silver sulfide (Ag₂S, AgS), iron oxide (Fe₃O₄), and the like. The passive layer can be grown via, for example, oxidation techniques, formed by gas phase reactions, etc.

At 1010 a polymer memory layer can be formed over the passive layer to form the memory cell component of the vertical JFET and memory cell. The polymer layer can be, for example, a conjugated organic polymer. The organic molecules can be cyclic or acyclic, and can be capable of self-assembly during formation or deposition. Examples of conjugated organic materials comprise one or more of polyacetylene (cis or trans); polyphenylacetylene (cis or trans); polydiphenylacetylene; polyaniline; poly (p-phenylene vinylene); polythiophene; polyporphyrins; porphyrinic macrocycles, thiol derivatized polyporphyrins; polymetallocenes such as polyferrocenes, polyphthalocyanines; polyvinylenes; polystiroles; and the like. Additionally, the properties of the polymer memory layer can be modified by doping with a suitable dopant. It is to be appreciated that the polymer layer can comprise inorganic material(s), and is not limited to organic polymers.

Finally, at 1012, a bitline can be formed over the polymer memory layer/cell, which can facilitate programming (e.g., read, write, erase, etc.) of the polymer memory cell with vertical JFET via manipulation of voltage(s) applied to the bitline and a wordline, or gate, of the vertical JFET. Such voltage manipulation can facilitate control of current permitted to pass through the JFET and/or memory cell, which in turn can provide control over the state of the memory cell.

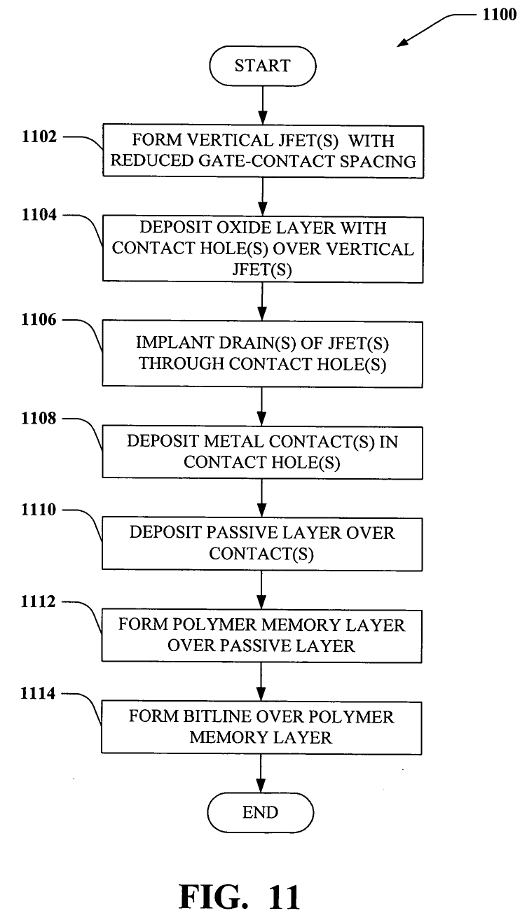

FIG. 11 illustrates a flow diagram of a methodology 1100 that facilitates reducing the critical dimension of a vertical JFET and associated memory cell in accordance with an aspect of the present invention. At 1102, a vertical JFET can be formed with reduced spacing between the gate and drain, as illustrated in FIG. 8. By mitigating the spacing between the gate and drain of the vertical JFET, the overall size vertical JFET itself can be restrained to facilitate achieving greater device density. An oxide layer, such as, for example, silicon dioxide, can be deposited over the vertical JFET, and contact hole(s) that are aligned with the JFET drain(s) can be provided therein at 1104. At 1106, a vertical JFET drain can be implanted through the contact hole. Then, a metal contact can be inserted into the contact hole at 1108. A passive layer can be deposited over the metal contact(s) at 1110, as described with reference to FIG. 10. A polymer memory layer can further be deposited over the passive layer to form the polymer memory cell(s) described herein at 1112. Finally, a bitline can be formed over the polymer memory cell via deposition of a suitable bitline metal at 1114. Thus, the methodology 1100 facilitates reducing the size of the vertical JFET and polymer memory cell to facilitate achieving smaller critical dimensions thereof, which in turn permit an increase in the number of such devices in a given area squared.

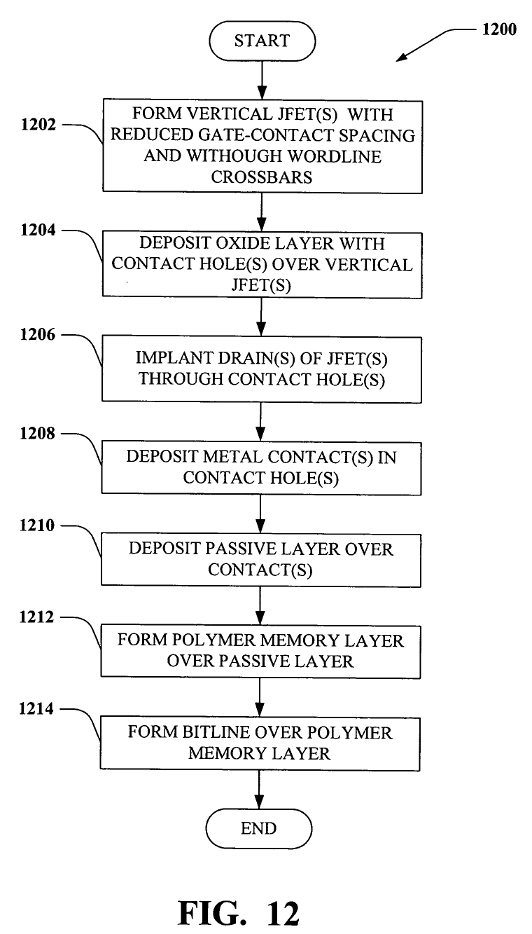

FIG. 12 is an illustration of a methodology 1200 that further facilitates critical dimension reduction in the vertical JFET and memory cell in accordance with an aspect of the present invention. At 1202, a vertical JFET can be formed with reduced spacing between the gate and drain, as described with reference to FIG. 11, and without crossbars between JFETs in a wordline (see, e.g., FIGS. 6 illustrating an array of vertical JFETs with crossbars, and FIG. 9, illustrating an array of vertical JFETs without crossbars). Elimination of crossbars between vertical JFETs facilitates achieving even greater device density than reduction of gate-to-drain spacing alone. At 1204, an oxide layer, such as, for example, silicon dioxide, can be deposited over the vertical JFET, and contact hole(s) that are aligned with the JFET drain(s) can be provided therein. At 1206, a vertical JFET drain can be implanted through the contact hole, and a metal contact can be inserted into the contact hole at 1208. A passive layer can be deposited over the metal contact(s) at 1210, as described with reference to FIG. 10. At 1212, polymer memory layer can further be deposited over the passive layer to form the polymer memory cell(s) described herein. Finally, a bitline can be formed over the polymer memory cell via deposition of a suitable metal at 1214. Thus, the methodology 1200 facilitates reducing the size of the vertical JFET and polymer memory cell from approximately 15 features-squared to about 8 features squared, which permits a substantial increase in device density to be realized, as compared with conventional methodologies.

What has been described above comprises examples of the present invention. It is, of course, not possible to describe every conceivable combination of components or methodologies for purposes of describing the present invention, but one of ordinary skill in the art can recognize that many further combinations and permutations of the present invention are possible. Accordingly, the present invention is intended to embrace all such alterations, modifications and variations that fall within the spirit and scope of the appended claims. Furthermore, to the extent that the term “comprises” is used in either the detailed description or the claims, such term is intended to be inclusive in a manner similar to the term “comprising” as “comprising” is interpreted when employed as a transitional word in a claim.

What is claimed is:

1. A semiconductor device that facilitates increasing device density in a memory cell array, comprising:
a vertical JFET that provides selectivity in the semiconductor device; and
a polymer memory cell that is controlled in part by internal current flow through the vertical JFET.

2. The semiconductor device of claim 1, the vertical JFET comprises a drain, a source, and a gate that is vertically positioned to surround the drain.

3. The semiconductor device of claim 2, the gate and drain are physically positioned to minimize any space there between to reduce critical dimension of the vertical JFET.

4. The semiconductor device of claim 1, the vertical JFET comprises a source, a drain, and a gate that extends along two opposite sides of the drain to permit positioning of a plurality of vertical JFETs in closer proximity to each other.

5. The semiconductor device of claim 4, the gate is a wordline.

6. The semiconductor device of claim 5, the wordline and drain abut one another to mitigate empty space there between and to reduce feature size of the semiconductor device.

7. The semiconductor device of claim 6, further comprising an oxide layer formed over the vertical JFET that has a contact hole aligned with the drain of the vertical JFET.

8. The semiconductor device of claim 7, further comprising a metal contact inserted into the contact hole.

9. The semiconductor device of claim 8, further comprising a passive layer formed over the metal contact and beneath the polymer memory cell, and operatively coupled to the drain of the vertical JFET by the metal contact.

10. The semiconductor device of claim 9, further comprising a bitline positioned over the polymer memory cell and arranged in a non-parallel orientation to the wordline.

11. A memory cell array comprising a plurality of the semiconductor device of claim 10.

12. The memory cell array of claim 10, at least two of the plurality of semiconductor devices are connected by a single bitline.

13. The memory cell array of claim 12, at least two of the plurality of semiconductor devices are connected by a single wordline.

14. A method for providing an array of semiconductor devices, comprising:
forming a plurality of vertical JFETs on a substrate;
constructing a plurality of polymer memory cells that are operably coupled to the vertical JFETs, and which are selectively controlled by current flow through the vertical JFETs; and
electrically coupling the plurality of memory cells to at least one bitline.

15. The method of claim 14, forming a vertical JFET comprises:
forming at least one wordline on a substrate;
forming a drain that is bordered on at least two sides by the wordline;
depositing an oxide layer over the at least one wordline;
forming a contact hole in the oxide layer aligned with the at least one wordline; and
doping the drain through the contact hole.

16. The method of claim 15, further comprising doping the substrate to provide a source for the vertical JFETs.

17. The method of claim 16, further comprising minimizing a gap between the wordline and the drain to reduce the feature size of the vertical JFET.

18. The method of claim 17, further comprising inserting a metal contact into the contact hole.

19. The method of claim 18, constructing a polymer memory cell comprises:
depositing a passive layer over the contact;
forming a polymer memory layer over the passive layer.

20. The method of claim 19, further comprising orienting bitlines substantially perpendicular to wordlines such that wordline and a bitline have a single intersection at which a semiconductor device is positioned in the array of semiconductor devices.

21. A system that facilitates providing a selective element to a memory cell in an array of memory cells, comprising:
means for constructing a vertical JFET that controls a state of a memory cell;
means for operatively coupling the vertical JFET to the memory cell; and
means for electrically connecting a plurality of memory cells coupled to vertical JFETs in an array.

22. The system of claim 21, further comprising means for selectively applying at least one voltage to the means for electrically connecting a plurality of memory cells coupled to vertical JFETs to permit control of the state of at least one memory cell in the array.
